(19) United States
(12) Patent Application Publication
(10) Pub. No.: US 2024/0272237 A1
(43) Pub. Date: Aug. 15, 2024

(54) LEAKAGE CURRENT DETECTION AND INTERRUPTION DEVICE FOR POWER CORD AND RELATED ELECTRICAL CONNECTORS AND ELECTRICAL APPLIANCES

(71) Applicant: Chengli LI, Suzhou (CN)

(72) Inventors: Chengli LI, Suzhou (CN); Long CHEN, Suzhou (CN)

(73) Assignee: Chengli LI, Suzhou (CN)

(21) Appl. No.: 18/169,756

(22) Filed: Feb. 15, 2023

(30) Foreign Application Priority Data
Feb. 13, 2023 (CN) 202310103339.3
Feb. 13, 2023 (CN) 202320192198.2

(51) Int. Cl. G01R 31/52; H02H 3/08

(52) U.S. Cl. CPC G01R 31/52; H02H 3/08

(57) ABSTRACT

A leakage current detection and interruption (LCDI) device includes a switch module for controlling an electrical connection between input and output ends of power supply lines; a leakage current detection module for generating a leakage fault signal when detecting a leakage current on the power supply lines; a drive module coupled to the leakage current detection module and the switch module, for controlling the switch module to disconnect or connect the electrical connection; a wireless communication module, coupled to the drive module and/or the leakage current detection module, for wirelessly communicating with a remote control device to allow the remote control device to perform at least one of: controlling the switch module to disconnect or connect the electrical connection, setting parameters of the LCDI device, and obtaining electrical information and/or fault information of the LCDI device. The LCDI device enables remote control and monitor, and has a simple electrical structure.

### BACKGROUND OF THE INVENTION

### Field of the Invention

This invention relates to electrical circuits, and in particular, it relates to a leakage current detection and interruption (LCDI) device for a power cord, and related electrical connectors and electrical appliances.

### Description of Related Art

With rapid development of technology, the number of appliances that people use in their homes is increasing, and home appliances are increasing becoming smart devices. There is an increased demand for leakage current detection and interruption (LCDI) devices that are safe and that allow remote monitor and control by users. Current LCDI devices have leakage current protection functions but do not enable users to perform remote monitor and control. When the user is not in the physical proximity of the appliances, they cannot monitor the operation of the appliances, such as whether they are functioning properly or have a fault.

### SUMMARY

In one aspect, the present invention provides a leakage current detection and interruption (LCDI) device, which includes: a switch module, coupled to power supply lines between an input end and an output end and configured to control an electrical connection between the input end and the output end; a leakage current detection module, configured to detect a leakage current on the power supply lines and to generate a leakage fault signal in response thereto; a drive module, coupled to the leakage current detection module and the switch module, and configured to control the switch module to disconnect or connect the electrical connection between the input end and output end; a wireless communication module, coupled to the drive module and/or the leakage current detection module, and configured to wirelessly communicate with a remote control device to allow the remote control device to perform at least one of: controlling the switch module to disconnect or connect the electrical connection between the input end and output end, setting parameters of the leakage current detection and interruption device, and obtaining electrical information and/or fault information of the leakage current detection and interruption device; and at least one power supply module, configured to supply a power to the leakage current detection module and the wireless communication module.

In some embodiments, the wireless communication module is configured to operate in a timed control mode, wherein in the timed control mode, the wireless communication module is configured to: receive control data from the remote control device, and in response to the control data including a control timing, control the switch module to disconnect or connect the electrical connection between the input end and output end based on the control data at a time indicated by the control timing.

In some embodiments, the wireless communication module is configured to: in response to the control data not including a timing of the commanded operation, control the switch module to disconnect or connect the electrical connection between the input end and output end based on the control data at a time that is either a pre-set timing or a timing indicated by a last control data.

In some embodiments, the wireless communication module is further configured to perform a countdown based on the control timing, and to either transmit countdown information to the remote control device at pre-set time intervals, or transmit the countdown information to the remote control device in response to a request from the remote control device.

In some embodiments, the wireless communication module is configured to operate in a real-time control mode, wherein in the real-time control mode, the wireless communication module receives control data from the remote control device, and controls the switch module to disconnect or connect the electrical connection between the input end and output end based on the control data.

In some embodiments, the wireless communication module controls the switch module to disconnect or connect the electrical connection between the input end and output end based on the control data by: generating a drive module trigger signal based on the control data; and providing the drive module trigger signal to the drive module or the leakage current detection module; and wherein in response to the drive module trigger signal, the drive module controls the switch module to disconnect or connect the electrical connection between the input end and output end.

In some embodiments, the wireless communication module is further configured to: receive the leakage fault signal and store fault information corresponding to the leakage fault signal; and generate a fault alarm signal based on the leakage fault signal, and transmits the alarm signal to the remote control device either at a time of generating the fault alarm signal or in response to a request from the remote control device.

In another aspect, the present invention provides an electrical power connection device, which includes a body and any of the above leakage current detection and interruption device disposed inside the body.

In yet another aspect, the present invention provides an electrical appliance, which includes an electrical load and an electrical power connection device coupled between a power supply and the electrical load, configured to supply power to the electrical load, wherein the electrical power connection device includes any of the above leakage current detection and interruption device.

The LCDI device according to embodiments of the present invention can allow the user to obtain electrical information and/or fault information f the LCDI device via remote control devices, as well as to set parameters of the leakage current detection and interruption device. This achieves remote control and monitoring of the LCDI device. Moreover, the LCDI device has a simple electrical structure, is low cost and reliable.

### BRIEF DESCRIPTION OF THE DRAWINGS

Preferred embodiments of the present invention are described with reference to the drawings. These drawings explain the embodiments and their operating principle, and only illustrate structures that are necessary to the understanding of the invention. These drawings are not to scale. In the drawings, like features are designated by like reference symbols. In the block diagrams, lines between blocks represent electrical or magnetic coupling of the blocks; the absence of lines between blocks does not mean the lack of coupling.

FIG. 1 is a block diagram of a leakage current detection and interruption device according to embodiments of the present invention.

FIG. 2 illustrates a leakage current detection and interruption device according to a first embodiment of the present invention.

FIG. 3 illustrates a leakage current detection and interruption device according to a second embodiment of the present invention.

FIG. 4 illustrates a leakage current detection and interruption device according to a third embodiment of the present invention.

FIG. 5 illustrates a leakage current detection and interruption device according to a fourth embodiment of the present invention.

### DETAILED DESCRIPTION OF PREFERRED EMBODIMENTS

Preferred embodiments of the present invention are described below with reference to the drawings. These drawings and descriptions explain embodiments of the invention but do not limit the invention. The described embodiments are not all possible embodiments of the present invention. Other embodiments are possible without departing from the spirit and scope of the invention, and the structure and/or logic of the illustrated embodiments may be modified. Thus, it is intended that the scope of the invention is defined by the appended claims.

Before describing the embodiments, some terms used in this disclosure are defined here to help the reader better understand this disclosure.

In this disclosure, terms such as “connect”, “couple”, “link” etc. should be understood broadly, without limitation to physical connection or mechanical connection, but can include electrical connection, and can include direct or indirection connections. Terms such as “a” and “one” do not limit the quantity, and refers to “at least one”.

In the descriptions below, terms such as “including” are intended to be open-ended and mean “including without limitation”, and can include other contents. “Based on” means “at least partly based on.” “An embodiment” means “at least one embodiment.” “Another embodiment” means “at least another embodiment,” etc. In this disclosure, the above terms do not necessarily refer to the same embodiments. Further, the various features, structures, materials or characteristics may be suitably combined in any of the one or more embodiments. Those of ordinary skill in the art may combine the various embodiments and various characteristics of the embodiments described herein when they are not contrary to each other.

Embodiments of the present invention provide a leakage current detection and interruption device that includes a wireless communication module for communication with remote control devices. It enables users to use the remote control device to remotely obtain electrical information and/or fault information and set control parameters of the leakage current detection and interruption device. This allows for remote control and monitoring. Further, the leakage current detection and interruption device has a simple electrical structure, is low cost, and reliable.

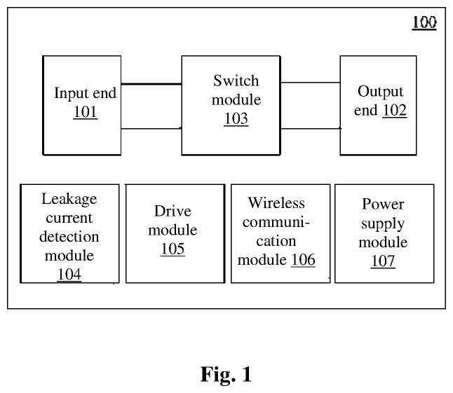

FIG. 1 is a block diagram of a leakage current detection and interruption device according to embodiments of the present invention. As shown in FIG. 1, the leakage current detection and interruption device 100 includes a switch module 103, a leakage current detection module 104, a drive module 105, a wireless communication module 106 and at least one power supply module 107.

The switch module 103 is coupled between the input end 101 and output end 102 of the power lines, and controls the electrical connection between the input end 101 and the output end 102. The leakage current detection module 104 functions to generate a leakage fault signal when a leakage fault is present on the power lines. When the power lines has a leakage fault, a leakage current is present on the power lines, and the leakage current detection module 104 detects such leakage current and generates the leakage fault signal. The drive module 105 is coupled to the leakage current detection module 104 and switch module 103, and controls the open/close state of the leakage current detection module 104 to disconnect or connect the electrical connection between the input end 101 and output end 102. When the leakage current detection module 104 generates the leakage fault signal, the drive module 105 receives such leakage fault signal, and in response thereto, drives the switch module 103 to disconnect the electrical connection between the input end 101 and output end 102.

The wireless communication module 106 is coupled to the drive module 105 and/or leakage current detection module 104, and communicates with remote control devices, to allow the remote control devices to perform at least one of the following functions: to control the switch module 103 to disconnect or connect the electrical connection between the input end 101 and output end 102; to set parameters of the leakage current detection and interruption device 100; and to obtain electrical information and/or fault information of the leakage current detection and interruption device 100.

The at least one power supply module 107 (there may be one or more power supply modules) supplies power to the leakage current detection module 104 and wireless communication module 106. The power supply module 107 may convert the AC (alternating current) power on the power supply lines to a DC (direct current) power and supply the DC power to the leakage current detection module 104 and wireless communication module 106.

The remote control device may be any suitable devices that has wireless communication functions, such as a smart phone, a notebook computer, a desktop computer, a tablet computer, a control station, a handheld control device, etc. The remote control device may include control software and/or mechanical control switches. The parameters includes any of the programable parameters of the leakage current detection and interruption device 100, such as programmed times for connecting and disconnecting electrical power, etc. It should be understood that the leakage current detection and interruption device 100 may further include an electrical measurement module such as current measurement module or voltage measurement module (not shown in the drawings), and the wireless communication module 106 may be further coupled to one of more of these measurement modules, receive electrical measurement data such as current and voltage values from these modules, and store the corresponding data in its memory and/or transmit the data to the remote control device (for example, it may transmit the data in response to receiving an inquiry from the remote control device). The electrical information may include one or more of the following for the leakage current detection and interruption device 100: real-time or historical electrical data, measurement time, number of measurements, trend plot, etc. Further, in addition to the leakage current detection module 104, the leakage current detection and interruption device 100 may further include other fault detection modules that detect other fault conditions such as leakage current fault, over-current fault, short circuit fault, overload fault, etc. The wireless communication module 106 may be coupled to one more of such fault detection modules, and in response to these modules detecting the corresponding fault conditions, receive the fault signals from the fault detection modules, store corresponding fault data in its memory and/or transmit the fault data to the remote control device (for example, it may transmit the fault data automatically when fault occurs, or transmit the fault data in response to receiving an inquiry from the remote control device). The fault data may include one or more of: the type of fault, the time it occurred, number of times that the same type of fault occurred in the past, suggestions for handling the fault, etc.

To summarize, the leakage current detection and interruption device 100 according to embodiments of the present invention can communicate with remote control devices via the wireless communication module 106, enabling the user to obtain electrical information and/or fault information via the remote control device 108, as well as to set parameters of the leakage current detection and interruption device. This achieves remote control and monitoring of the leakage current detection and interruption device 100. Moreover, the leakage current detection and interruption device 100 has a simple electrical structure, is low cost and reliable.

In some embodiments, the wireless communication module 106 can be operated in a timed control mode. In this mode, the wireless communication module 106 receives control data from the remote control device 108, and if the control data indicates a control timing, then the wireless communication module 106 controls the switch module 103 to disconnect or connect the electrical connection between the input end 101 and output end 102 at the time indicated by the control data. More specifically, for example, the control data may include a control command to disconnect or connect the power and a specific time of the commanded operation (e.g., to disconnect power at 18:00 hours), or a control command and the time interval until the commanded operation (e.g., to disconnect power in 5 hours). The user may use the remote control device 108 to set the control commands and the timing. After the wireless communication module 106 receives the control data, it controls the switch module 103 to disconnect or connect power as instructed by the control data at the time indicated by the control data.

The wireless communication module 106 may be coupled to one or both of the leakage current detection module 104 and drive module 105; when it needs to control the switch module 103, the wireless communication module 106 generates an appropriate drive module trigger signal based on the control data, and provides the trigger signal to the drive module 105 or leakage current detection module 104. In turn, the drive module 105 controls the switch module 103 to disconnect or connect the electrical connection between the input end 101 and output end 102.

In some embodiments, in the timed control mode, if the control data does not indicate a timing of the commanded operation, e.g. the user did not set the control timing (time point or time interval), then the timing of the operation may be a pre-set timing (e.g. a default timing), or the timing indicated by the last control data, so the wireless communication module 106 may control the switch module 103 based on the control data and such control timing, to disconnect or connect the electrical connection between the input end 101 and output end 102. By using the above timed control mode, the user may set the on/off timing of the electrical appliance based on his need.

In some embodiments, the wireless communication module 106 may perform a countdown based on the control timing, and can transmit countdown information to the remote control device 108 at pre-set time intervals. Further, the remote control device 108 may transmit requests to the wireless communication module 106 regarding the countdown, and the wireless communication module transmits the countdown information to the remote control device in response to such requests. The user may check countdown information via the remote control device.

In some embodiments, the wireless communication module 106 may operate in a real-time control mode. In the real-time control mode, the wireless communication module 106 receives control data from the remote control device 108, and in response thereto, control the switch module 103 to disconnect or connect the electrical connection between the input end 101 and output end 102. More specifically, for example, the control data may include a control command to disconnect or connect the power. The user may use the remote control device 108 to set the control commands. When the wireless communication module 106 receives the control data, it controls the switch module 103 to disconnect or connect power as instructed by the control command. The wireless communication module 106 may be coupled to one or both of the leakage current detection module 104 and drive module 105; when it needs to control the switch module 103, the wireless communication module 106 generates an appropriate drive module trigger signal based on the control data, and provides the trigger signal to the drive module 105 or leakage current detection module 104. In turn, the drive module 105 controls the switch module 103 to disconnect or connect the electrical connection between the input end 101 and output end 102. Using the real-time control mode, the user may conveniently control the on/off of the electrical appliance in real time based on his need.

In some embodiments, the wireless communication module 106 may receive the leakage fault signal and store corresponding fault information, and generate a fault alarm signal based on the leakage fault signal and transmits the alarm signal to the remote control device. This way, the fault condition may be timely reported to the user, allowing the user to deal with the fault condition. Further, the remote control device 108 may issue inquiries to the wireless communication module 106, and the wireless communication module 106 transmits the fault information to the remote control device in response to the inquiry.

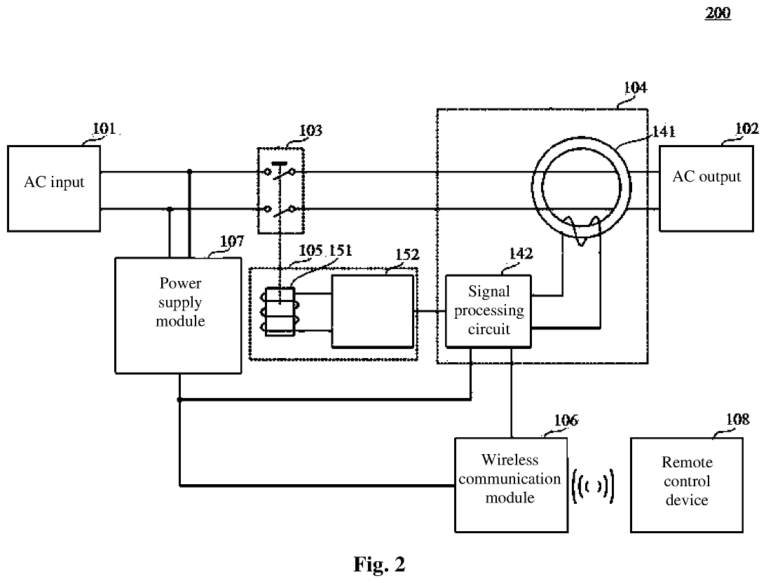

FIG. 2 illustrates a leakage current detection and interruption device 200 according to a first embodiment of the present invention. As shown in FIG. 2, the leakage current detection and interruption device 200 includes a switch module 103, leakage current detection module 104, drive module 105, wireless communication module 106, and power supply module 107. The power lines include two current-carrying wires. As shown in FIG. 2, the switch module 103 includes a reset switch which controls the electrical connection of the two current-carrying wires between the input end 101 and output end 102. The leakage current detection module 104 includes a leakage current detection ring 141 through which the two current-carrying wires pass, and a signal processing circuit 142 coupled in series to the leakage current detection ring 141. The signal processing circuit 142 may include, for example, a leakage current detection chip and related circuits. The drive module 105 includes a drive coil 151 and a drive circuit 152 coupled in series to the drive coil 151. The drive circuit 152 may include, for example, at least one semiconductor device such as a silicon controlled rectifier, bipolar transistor, field effect transistor, photoelectric coupling element, or the like. The signal processing circuit 142 is coupled in series with the drive circuit 152. The drive coil 151 generates an electromagnetic force that drives the switch module 103. The drive circuit 152 causes the drive coil 151 to generate the electromagnetic force when the signal processing circuit 142 generates a leakage fault signal, to drive the switch module 103 to disconnect the electrical connection between the input end 101 and output end 102.

The wireless communication module 106 is coupled to the signal processing circuit 142, and wirelessly communicates with the remote control device 108. By communicating with the wireless communication module 106, the remote control device 108 can control the switch module 103 to disconnect or connect the electrical connection between the input end 101 and output end 102, set parameters of the leakage current detection and interruption device 200, and obtain electrical information and/or fault information of the leakage current detection and interruption device. The power supply module 107 is coupled to the two current-carrying wires, the signal processing circuit 142 and the wireless communication module 106, and functions to convert the AC power on the current-carrying wires to a DC power and supply it to the signal processing circuit 142 and the wireless communication module 106.

Under normal working conditions, the two current-carrying wires are coupled to the power grid, and the switch module 103 is in the reset (i.e. closed) state, so the AC input end 101 and AC output end 102 are electrically connected to each other. When one or both of the two current-carrying wires has a leakage current, i.e., the power lines have a leakage current or leakage fault, the leakage current detection ring 141 detects a current imbalance on the two current-carrying wires, and generates a corresponding leakage signal (e.g., an induced voltage), and couples the leakage signal to the signal processing circuit 142. The signal processing circuit 142 compares the leakage signal to a threshold value, and when the leakage signal is greater than the threshold value, the signal processing circuit 142 generates the leakage fault signal, and couples the leakage fault signal to the drive circuit 152. This triggers the drive circuit 152, which in turn causes a change in the current flowing through the drive coil 151, thereby generating a corresponding electromagnetic force to drive the switch module 103 to disconnect the electrical connection between the input end 101 and output end 102. The signal processing circuit 142 further couples the leakage fault signal to the wireless communication module 106. The wireless communication module 106 stores the fault data corresponding to the leakage fault signal in its memory and/or transmit the fault data to the remote control device 108. The fault data may include one or more of: the type of fault (leakage fault), the time it occurred, number of times that the same type of fault occurred in the past, suggestions for handling the fault, etc.

The wireless communication module 106 can operate in a real-time control mode or a timed control mode. For example, a user may install a remote control application on the smart phone or computer, and use the application to select real-time control mode or timed control mode, and set relevant control parameters in the selected mode. In other examples, a hand-held control device may be provided with a mechanical mode selection switch to allow the user to select real-time control mode or timed control mode.

In the real-time control mode, the user transmits control data via the wireless communication module 106 to the remote control device 108. The control data may include a control command to disconnect or connect the power. In response to receiving such control command, the wireless communication module 106 controls the switch module 103 to disconnect or connect the electrical connection. For example, the user uses the remote control device 108 to select the real-time control mode and set the control data to disconnect the electrical connection. The remote control device 108 transmits the control data to the wireless communication module 106. When the wireless communication module 106 receives the control data, it generates a drive module trigger signal (e.g., a simulated leakage signal), and provides the drive module trigger signal to the signal processing circuit 142. The signal processing circuit 142 compares the drive module trigger signal to the threshold value, and when the drive module trigger signal is greater than the threshold value, the signal processing circuit 142 generates a leakage fault signal and couples the signal to the drive circuit 152. This triggers the drive circuit 152, which in turn causes a change in the current flowing through the drive coil 151, thereby generating a corresponding electromagnetic force to drive the switch module 103 to disconnect the electrical connection between the input end 101 and output end 102.

In the timed control mode, the user transmits control data via the wireless communication module 106 to the remote control device 108. The control data may include a control command to disconnect or connect the power. If the control data includes a timing of the commanded operation, such as a specific time point or a time interval from the present time, the wireless communication module 106 controls the switch module 103 to disconnect or connect the electrical connection at the time set by the control data. If the control data does not indicate a timing of the commanded operation, e.g. it does not include the time point or time interval, then the wireless communication module 106 may control the switch module 103 to disconnect or connect the electrical connection based on a pre-set timing or the timing indicated by the last control data. For example, if the user uses the remote control device 108 to select the timed control mode and sets a control data to disconnect the power a specific time point, the remote control device 108 transmits this control data to the wireless communication module 106. As the control data includes the control timing, the wireless communication module 106 performs a countdown based on the control timing, and transmits countdown information to the remote control 108 device at pre-set time intervals. If, on the other hand, the control data does not include control timing, the wireless communication module 106 performs a countdown based on the pre-set timing or the timing indicated by the last control data, and transmits countdown information to the remote control 108 device at pre-set time intervals. The user may check countdown information via the remote control device 108. When the time of operation arrives at the end of the countdown, the wireless communication module 106 generates a drive module trigger signal (e.g., a simulated leakage signal), and provides the drive module trigger signal to the signal processing circuit 142. The signal processing circuit 142 compares the drive module trigger signal to the threshold value, and when the drive module trigger signal is greater than the threshold value, the signal processing circuit 142 generates a leakage fault signal and couples the signal to the drive circuit 152. This triggers the drive circuit 152, which in turn causes a change in the current flowing through the drive coil 151, thereby generating a corresponding electromagnetic force to drive the switch module 103 to disconnect the electrical connection between the input end 101 and output end 102.

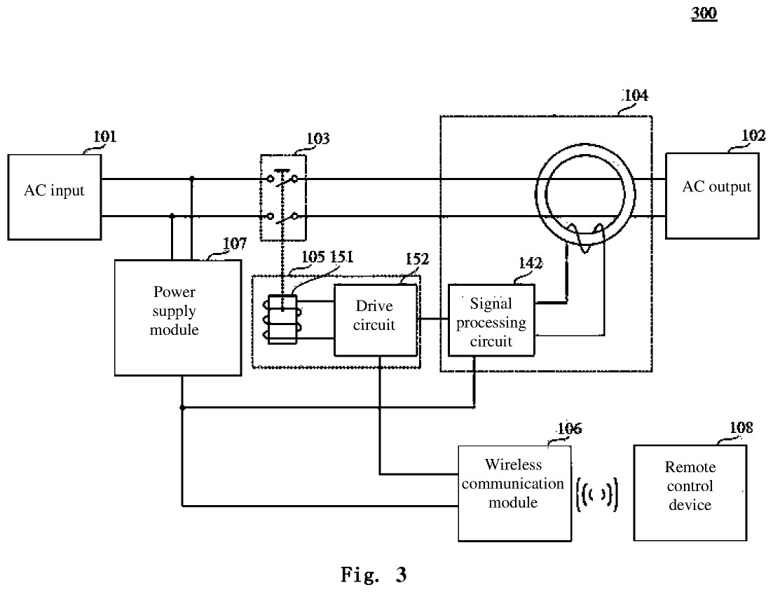

FIG. 3 illustrates a leakage current detection and interruption device 300 according to a second embodiment of the present invention. The embodiment of FIG. 3 is similar to the embodiment of FIG. 2, but the wireless communication module 106 is coupled to the drive circuit 152 of the drive module 105, rather than to the signal processing circuit 142.

Under normal working conditions, the two current-carrying wires are coupled to the power grid, and the switch module 103 is in the reset (i.e. closed) state, so the AC input end 101 and AC output end 102 are electrically connected to each other. When one or both of the two current-carrying wires has a leakage current, i.e., the power lines have a leakage current or leakage fault, the leakage current detection ring 141 detects a current imbalance on the two current-carrying wires, and generates a corresponding leakage signal (e.g., an induced voltage), and couples the leakage signal to the signal processing circuit 142. The signal processing circuit 142 compares the leakage signal to a threshold value, and when the leakage signal is greater than the threshold value, the signal processing circuit 142 generates the leakage fault signal, and couples the leakage fault signal to the drive circuit 152. This triggers the drive circuit 152, which in turn causes a change in the current flowing through the drive coil 151, thereby generating a corresponding electromagnetic force to drive the switch module 103 to disconnect the electrical connection between the input end 101 and output end 102.

The wireless communication module 106 can operate in a real-time control mode or a timed control mode. For example, a user may install a remote control application on the smart phone or computer, and use the application to select real-time control mode or timed control mode, and set relevant control parameters in the selected mode. In other examples, a hand-held control device may be provided with a mechanical mode selection switch to allow the user to select real-time control mode or timed control mode.

In the real-time control mode, the user transmits control data via the wireless communication module 106 to the remote control device 108. The control data may include a control command to disconnect or connect the power. In response to receiving such control command, the wireless communication module 106 controls the switch module 103 to disconnect or connect the electrical connection. For example, the user may use the remote control device 108 to select the real-time control mode, and set the control data to disconnect the electrical connection. The remote control device 108 transmits the control data to the wireless communication module 106. When the wireless communication module 106 receives the control data, it generates a drive module trigger signal (e.g., a simulated leakage fault signal), and provides the drive module trigger signal to the drive circuit 152. This triggers the drive circuit 152, which in turn causes a change in the current flowing through the drive coil 151, thereby generating a corresponding electromagnetic force to drive the switch module 103 to disconnect the electrical connection between the input end 101 and output end 102.

In the timed control mode, the user transmits control data via the wireless communication module 106 to the remote control device 108. The control data may include a control command to disconnect or connect the power. If the control data includes a timing of the commanded operation, such as a specific time point or a time interval from the present time, the wireless communication module 106 controls the switch module 103 to disconnect or connect the electrical connection at the time set by the control data. If the control data does not indicate a timing of the commanded operation, e.g. it does not include the time point or time interval, then the wireless communication module 106 may control the switch module 103 to disconnect or connect the electrical connection based on a pre-set timing or the timing indicated by the last control data. For example, if the user uses the remote control device 108 to select the timed control mode and sets a control data to disconnect the power a specific time point or time interval, the remote control device 108 transmits this control data to the wireless communication module 106. As the control data includes the control timing, the wireless communication module 106 performs a countdown based on the control timing, and transmits countdown information to the remote control 108 device at pre-set time intervals. If, on the other hand, the control data does not include control timing, the wireless communication module 106 performs a countdown based on the pre-set timing or the timing indicated by the last control data, and transmits countdown information to the remote control 108 device at pre-set time intervals. The user may check countdown information via the remote control device 108. When the time of operation arrives at the end of the countdown, the wireless communication module 106 generates a drive module trigger signal (e.g., a simulated leakage fault signal), and provides the drive module trigger signal to the drive circuit 152. This triggers the drive circuit 152, which in turn causes a change in the current flowing through the drive coil 151, thereby generating a corresponding electromagnetic force to drive the switch module 103 to disconnect the electrical connection between the input end 101 and output end 102.

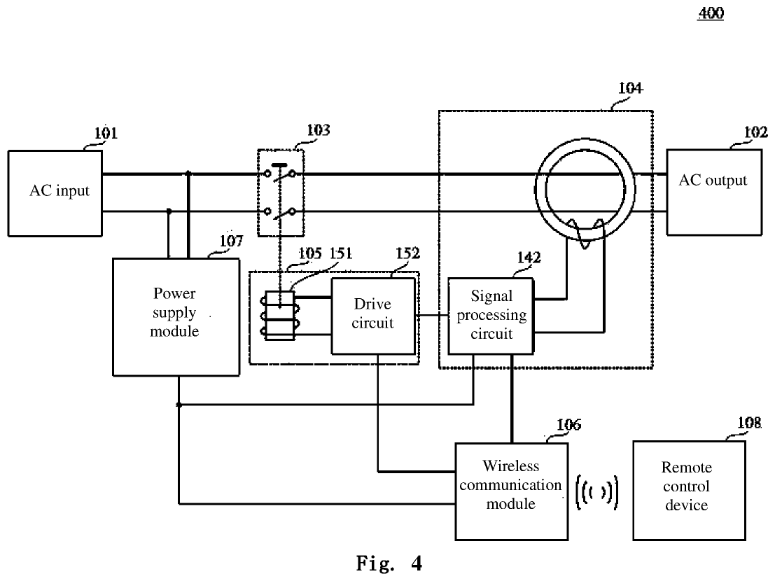

FIG. 4 illustrates a leakage current detection and interruption device 400 according to a third embodiment of the present invention. The embodiment of FIG. 4 is similar to the embodiment of FIG. 2, but the wireless communication module 106 is coupled to both the signal processing circuit 142 of the leakage current detection module 104 and the drive circuit 152 of the drive module 105.

Under normal working conditions, the two current-carrying wires are coupled to the power grid, and the switch module 103 is in the reset (i.e. closed) state, so the AC input end 101 and AC output end 102 are electrically connected to each other. When one or both of the two current-carrying wires has a leakage current, i.e., the power lines have a leakage current or leakage fault, the leakage current detection ring 141 detects a current imbalance on the two current-carrying wires, generates a corresponding leakage signal (e.g., an induced voltage), and couples the leakage signal to the signal processing circuit 142. The signal processing circuit 142 compares the leakage signal to a threshold value, and when the leakage signal is greater than the threshold value, the signal processing circuit 142 generates the leakage fault signal, and couples the leakage fault signal to the drive circuit 152. This triggers the drive circuit 152, which in turn causes a change in the current flowing through the drive coil 151, thereby generating a corresponding electromagnetic force to drive the switch module 103 to disconnect the electrical connection between the input end 101 and output end 102. The signal processing circuit 142 further couples the leakage fault signal to the wireless communication module 106. The wireless communication module 106 stores fault data corresponding to the leakage fault signal in its memory and/or transmit the fault data to the remote control device 108. The fault data may include one or more of: the type of fault (leakage fault), the time it occurred, number of times that the same type of fault occurred in the past, suggestions for handling the fault, etc.

The wireless communication module 106 can operate in a real-time control mode or a timed control mode. For example, a user may install a remote control application on the smart phone or computer, and use the application to select real-time control mode or timed control mode, and set relevant control parameters in the selected mode. In other examples, a hand-held control device may be provided with a mechanical mode selection switch to allow the user to select real-time control mode or timed control mode.

In the real-time control mode, the user transmits control data via the wireless communication module 106 to the remote control device 108. The control data may include a control command to disconnect or connect the power. In response to receiving such control command, the wireless communication module 106 controls the switch module 103 to disconnect or connect the electrical connection. For example, the user uses the remote control device 108 to select the real-time control mode, and set the control data to disconnect the electrical connection. The remote control device 108 transmits the control data to the wireless communication module 106. When the wireless communication module 106 receives the control data, it generates a drive module trigger signal (e.g., a simulated leakage fault signal), and provides the drive module trigger signal to the drive circuit 152. This triggers the drive circuit 152, which in turn causes a change in the current flowing through the drive coil 151, thereby generating a corresponding electromagnetic force to drive the switch module 103 to disconnect the electrical connection between the input end 101 and output end 102.

In the timed control mode, the user transmits control data via the wireless communication module 106 to the remote control device 108. The control data may include a control command to disconnect or connect the power. If the control data includes a timing of the commanded operation, such as a specific time point or a time interval from the present time, the wireless communication module 106 controls the switch module 103 to disconnect or connect the electrical connection at the time indicated by the control data. If the control data does not indicate a timing of the commanded operation, e.g. it does not include the time point or time interval, then the wireless communication module 106 may control the switch module 103 to disconnect or connect the electrical connection based on a pre-set timing or the timing indicated by the last control data. For example, if the user uses the remote control device 108 to select the timed control mode and sets a control data to disconnect the power a specific time point, the remote control device 108 transmits this control data to the wireless communication module 106. As the control data includes the control timing, the wireless communication module 106 performs a countdown based on the control timing, and transmits countdown information to the remote control 108 device at pre-set time intervals. If, on the other hand, the control data does not include control timing, the wireless communication module 106 performs a countdown based on the pre-set timing or the timing indicated by the last control data, and transmits countdown information to the remote control 108 device at pre-set time intervals. The user may check countdown information via the remote control device 108. When the time of operation arrives at the end of the countdown, the wireless communication module 106 generates a drive module trigger signal (e.g., a simulated leakage fault signal), and provides the drive module trigger signal to the drive circuit 152. This triggers the drive circuit 152, which in turn causes a change in the current flowing through the drive coil 151, thereby generating a corresponding electromagnetic force to drive the switch module 103 to disconnect the electrical connection between the input end 101 and output end 102.

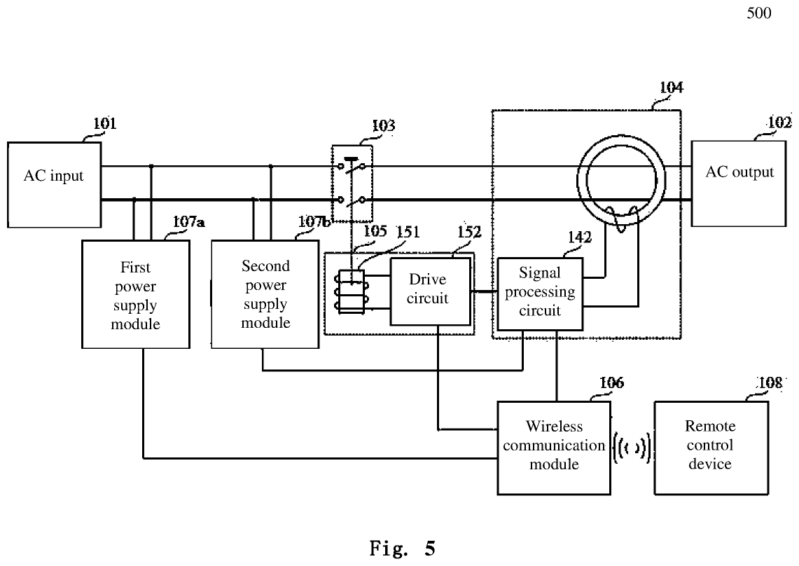

FIG. 5 illustrates a leakage current detection and interruption device 500 according to a fourth embodiment of the present invention. The embodiment of FIG. 5 is similar to the embodiment of FIG. 4, but includes two power supply modules 107a and 107b. The first power supply module 107a is coupled to the two current-carrying wires and the wireless communication module 106, and converts the AC power on the two current-carrying wires to a DC power and supplies it to the wireless communication module 106. The second power supply module 107b is coupled to the two current-carrying wires and the signal processing circuit 142, and converts the AC power on the two current-carrying wires to a DC power and supplies it to the signal processing circuit 142. The operation principles are otherwise similar to those of the embodiment of FIG. 4.

In a second aspect, the present invention provides an electrical power connection device, which includes a body, and a leakage current detection and interruption device of any of the above embodiments disposed inside the body.

In a third aspect, the present invention provides an electrical appliance, which includes an electrical load and an electrical power connection device coupled between a power supply and the electrical load and configured to supply power to the electrical load, where the electrical power connection device includes a leakage current detection and interruption device of any of the above embodiments.

While the present invention is described above using specific examples, these examples are only illustrative and do not limit the scope of the invention. It will be apparent to those skilled in the art that various modifications, additions and deletions can be made to the leakage current detection and interruption device of the present invention without departing from the spirit or scope of the invention.

What is claimed is:

1. A leakage current detection and interruption (LCDI) device, comprising:
a switch module, coupled to power supply lines between an input end and an output end and configured to control an electrical connection between the input end and the output end;
a leakage current detection module, configured to detect a leakage current on the power supply lines and to generate a leakage fault signal in response thereto;
a drive module, coupled to the leakage current detection module and the switch module, and configured to control the switch module to disconnect or connect the electrical connection between the input end and output end;
a wireless communication module, coupled to the drive module and/or the leakage current detection module, and configured to wirelessly communicate with a remote control device to allow the remote control device to perform at least one of: controlling the switch module to disconnect or connect the electrical connection between the input end and output end, setting parameters of the leakage current detection and interruption device, and obtaining electrical information and/or fault information of the leakage current detection and interruption device; and
at least one power supply module, configured to supply a power to the leakage current detection module and the wireless communication module.

2. The LCDI device of claim 1, wherein the wireless communication module is configured to operate in a timed control mode, wherein in the timed control mode, the wireless communication module is configured to:
receive control data from the remote control device, and
in response to the control data including a control timing, control the switch module to disconnect or connect the electrical connection between the input end and output end based on the control data at a time indicated by the control timing.

3. The LCDI device of claim 2, wherein the wireless communication module is configured to:
in response to the control data not including a timing of the commanded operation, control the switch module to disconnect or connect the electrical connection between the input end and output end based on the control data at a time that is either a pre-set timing or a timing indicated by a last control data.

4. The LCDI device of claim 2, wherein the wireless communication module is further configured to perform a countdown based on the control timing, and to
either transmit countdown information to the remote control device at pre-set time intervals, or transmit the countdown information to the remote control device in response to a request from the remote control device.

5. The LCDI device of claim 2, wherein the wireless communication module controls the switch module to disconnect or connect the electrical connection between the input end and output end based on the control data by:
generating a drive module trigger signal based on the control data; and
providing the drive module trigger signal to the drive module or the leakage current detection module; and
wherein in response to the drive module trigger signal, the drive module controls the switch module to disconnect or connect the electrical connection between the input end and output end.

6. The LCDI device of claim 1, wherein the wireless communication module is configured to operate in a real-time control mode, wherein in the real-time control mode, the wireless communication module receives control data from the remote control device, and controls the switch module to disconnect or connect the electrical connection between the input end and output end based on the control data.

7. The LCDI device of claim 2, wherein the wireless communication module controls the switch module to disconnect or connect the electrical connection between the input end and output end based on the control data by:
generating a drive module trigger signal based on the control data; and
providing the drive module trigger signal to the drive module or the leakage current detection module; and
wherein in response to the drive module trigger signal, the drive module controls the switch module to disconnect or connect the electrical connection between the input end and output end.

8. The LCDI device of claim 1, wherein the wireless communication module is further configured to:
receive the leakage fault signal and store fault information corresponding to the leakage fault signal; and
generate a fault alarm signal based on the leakage fault signal, and transmits the alarm signal to the remote control device either at a time of generating the fault alarm signal or in response to a request from the remote control device.

9. An electrical power connection device, comprising:
a body; and
a leakage current detection and interruption device of claim 1, disposed inside the body.

10. An electrical appliance, comprising:
an electrical load; and
an electrical power connection device coupled between a power supply and the electrical load, configured to supply power to the electrical load, wherein the electrical power connection device includes a leakage current detection and interruption device of claim 1.
